(19) United States
(12) Patent Application Publication
(10) Pub. No.: US 2005/0263788 A1
(43) Pub. Date: Dec. 1, 2005

(54) Heterojunction field effect semiconductor device

(75) Inventors: Tetsuo Kunii, Tokyo (JP); Yoshitsugu Yamamoto, Tokyo (JP); Yoshitaka Kamo, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/091,474

(22) Filed: Mar. 29, 2005

(30) Foreign Application Priority Data
May 26, 2004 (JP) 2004-155681

(51) Int. Cl. H01L 31/072

(52) U.S. Cl. 257/192; 257/194

(57) ABSTRACT

A heterojunction field effect transistor comprises a semi-insulating GaAs substrate, an n-InGaAs channel layer on the substrate, and a barrier layer on the n-InGaAs channel layer. The barrier layer is composed of a substantially fully depleted p-AlGaAs layer between two i-AlGaAs layers. A gate electrode is in Schottky contact with the barrier layer. Since the p-AlGaAs layer raises the barrier height in the barrier layer higher than the Schottky barrier, forward gate current is suppressed. In addition, the breakdown voltage is improved since a longer depletion region extends toward the drain side when a reverse bias is applied between the gate and the drain.

### BACKGROUND OF THE INVENTION

1. Field of the Invention

The present invention relates to heterojunction-used field effect semiconductor devices. In particular, the invention relates to heterojunction field effect semiconductor devices for use in high power amplifiers, etc. for the micro wave to millimeter wave bands.

2. Description of the Related Art

Recently, amplifiers used for the micro wave to millimeter wave bands are facing further intensifying demands for higher power output. Accordingly, heterojunction field effect transistors have begun to be used in enhancement mode due to the advantage in attaining high gains. The heterojunction field effect transistors are such as High Electron Mobility Transistors (hereinafter referred to as HEMTs), which use a modulation-doped structure, and Doped Channel Heterojunction Field Effect Transistors (hereinafter referred to as DCHFETs).

In the HEMT and in the DCHFET, a gate electrode and a barrier layer form a Schottky barrier. If the device is used in enhancement mode, the maximum forward voltage applicable to the gate electrode is determined by the height of the Schottky barrier. It is difficult to raise the height of the Schottky barrier since the materials performing the Schottky junction determine the height of the Schottky barrier.

Accordingly, when the heterojunction field effect transistor operates as a three-terminal device with a forward bias applied to the gate electrode, the forward gate current increases and causes negative feedback to the gate bias. In particular, if the threshold voltage Vth of a heterojunction field effect transistor to be operated with a forward bias applied to the gate electrode is low, this transistor involves the problem of low saturation output.

A widely known method to solve this problem is to form a pn junction composed of a p-type layer and an n-type layer in the barrier layer. The pn junction is formed to raise the height of the barrier. That is, the conduction band energy level difference between the p-type layer and the n-type layer, which form the pn junction, serves as the barrier height. Therefore, it is possible to raise the barrier height as compared with that determined by the material of the n-type layer and the material of the Schottky electrode. Consequently, this method allows a higher forward voltage. (For example, refer to the description in Paragraph No. [0011] and FIG. 1 in Japanese Patent Laid-open No. 2002-124663)

However, as a result of raising the barrier height of a heterojunction field effect transistor by forming a pn junction composed of a p-type layer and n-type layer in the barrier layer, a heavily-doped n-type semiconductor layer exists in the barrier layer. This may suppress the forward gate current. However, when a reverse bias is applied to the gate, a potential gradient in heavily doped n-type semiconductor layer becomes steep. The electric field strength in this n-type semiconductor layer is intensified. As a result, a problem arises in that the breakdown gate voltage cannot be made high.

Furthermore, impurity density may be raised in the p-type semiconductor layer as well as in the n-type semiconductor layer in order to suppress the forward gate electrode current. In that case, a problem arises in that pn junction determines the reverse breakdown gate voltage since the electric field strength in the pn junction is intensified.

### SUMMARY OF THE INVENTION

The present invention was made to solve the problem mentioned above. It is a primary object of the present invention to provide a heterojunction field effect semiconductor device where the barrier in the barrier layer is made higher than the Schottky barrier so as to suppress the forward gate bias current while raising the breakdown gate voltage.

According to one aspect of the invention, there is provided a heterojunction field effect semiconductor device comprising: a semi-insulating semiconductor substrate; a n-type semiconductor channel layer disposed on the substrate; a barrier layer disposed on the channel layer and composed of only either a substantially fully depleted p-type semiconductor layer or a substantially fully depleted p-type semiconductor layer and non-doped semiconductor layers;a gate electrode disposed on the barrier layer and made in Schottky contact with the barrier layer; and a source electrode and a drain electrode disposed on the barrier layer, facing each other through the gate electrode.

Accordingly, in the heterojunction field effect semiconductor device according to the present invention, the barrier layer is composed of only either a substantially fully depleted p-type semiconductor layer or a substantially fully depleted p-type semiconductor layer and non-doped semiconductor layers. Hence, the p-type semiconductor layer makes the barrier in the barrier layer being higher than the Schottky barrier so as to suppress the forward gate current. In addition, a longer depletion layer grows toward the drain electrode when a reverse bias is applied to between the gate electrode and the drain electrode. Thus, the breakdown gate voltage is raised.

According to another aspect of the invention, there is provided a heterojunction field effect semiconductor device comprising: a semi-insulating semiconductor substrate; a n-type semiconductor channel layer disposed on the substrate; a non-doped barrier layer disposed on the channel layer; a gate electrode disposed on the barrier layer and made in Schottky contact with the barrier layer; a p-type semiconductor layer which is substantially fully depleted, disposed on the barrier layer, partly burying the sides of the gate electrode; and a source electrode and a drain electrode that are disposed on the p-type semiconductor layer, facing each other through the gate electrode.

Accordingly, the potential barrier near the gate electrode is made higher than the Schottky barrier-based potential barrier. This makes it possible to suppress the forward gate current and therefore raise the saturation output. In addition, since a longer depletion layer grows toward the drain side when a reverse bias is applied to between the gate and the drain, the intensification of electric field near the gate electrode can be mitigated to raise the breakdown gate voltage.

According to still another aspect of the invention, there is provided a heterojunction field effect semiconductor device comprising: a semi-insulating semiconductor substrate; a channel layer of non-doped semiconductor disposed on the substrate; a barrier layer disposed on the channel layer, and composed of only either a substantially fully depleted p-type semiconductor layer or a substantially fully depleted p-type semiconductor layer and non-doped semiconductor layers; a gate electrode disposed on the barrier layer; and a source electrode and a drain electrode disposed on the barrier facing each other through the gate electrode.

Accordingly, the p-type semiconductor layer makes the potential barrier in the barrier layer higher than the Schottky barrier-based potential barrier. In addition, since the potential barrier near the gate electrode is further raised than the Schottky barrier-based potential barrier, the forward gate current can be suppressed. It is therefore possible to raise the saturation output.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a cross-sectional view of a heterojunction field effect transistor according to an embodiment of the present invention.

FIG. 2 is a cross-sectional view of an alternative heterojunction field effect transistor according to one embodiment of the present invention.

FIG. 3 is a cross-sectional view of another alternative heterojunction field effect transistor according to one embodiment of the present invention.

FIG. 4 is a cross-sectional view of another heterojunction field effect transistor according to another embodiment of the present invention.

FIG. 5 is a cross-sectional view of an alternative heterojunction field effect transistor according to one embodiment of the present invention.

FIG. 6 is a cross-sectional view of another alternative heterojunction field effect transistor according to one embodiment of the present invention.

FIG. 7 is a cross-sectional view of another heterojunction field effect transistor according to another embodiment of the present invention.

FIG. 8 is a cross-sectional view of an alternative heterojunction field effect transistor according to one embodiment of the present invention.

In all figures, the substantially same elements are given the same reference numbers.

### DESCRIPTION OF THE PREFERRED EMBODIMENTS

### First Embodiment

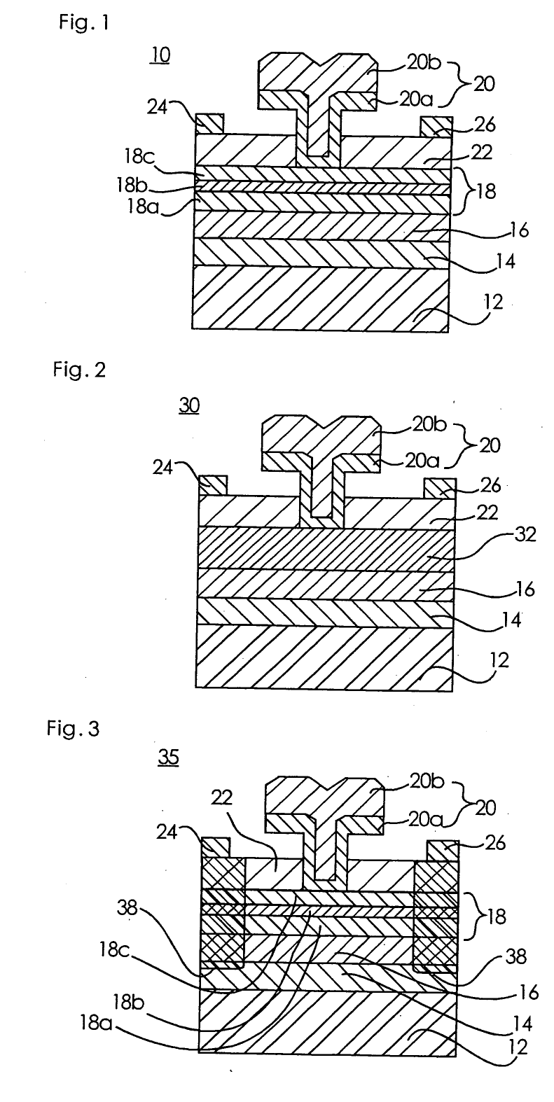

FIG. 1 is a cross-sectional view of a heterojunction field effect transistor according to an embodiment of the present invention.

FIG. 1 shows a DCHFET 10 of the first embodiment.

The DCHFET 10 uses a semi-insulating GaAs substrate 12 serving as a semi-insulating semiconductor substrate. On this GaAs substrate 12, a buffer layer 14 is disposed. The buffer layer 14 is composed of a 450 nm-thick superlattice layer and a 50 nm-thick non-doped GaAs layer disposed thereon. The superlattice layer is formed by depositing a 5 nm-thick GaAs layer and a 5 nm-thick AlGaAs layer repeatedly and alternately on the GaAs substrate 12. (Hereinafter, “i-”, “n-” and “p-” will be used to mean “non-doped”, “n conductivity type”, and “p conductivity type”, respectively.)

On this buffer layer 14, a 30 nm-thick n-InGaAs layer 16 is disposed serving as a channel layer. This n-InGaAs layer 16 has an impurity concentration of 1×10¹⁸ cm⁻³.

On this n-InGaAs layer 16, a barrier layer 18 is disposed. In this first embodiment, the thickness of the barrier layer 18 is, for example, 25 nm. The barrier layer 18 is composed of: an i-AlGaAs layer 18a disposed directly on the n-InGaAs layer 16; a p-AlGaAs layer 18b of, for example, 5 nm in thickness disposed on the i-AlGaAs layer 18a; and an i-AlGaAs layer 18c disposed on the p-AlGaAs layer 18b. The p-AlGaAs layer 18b has an impurity concentration of 1×10¹⁸ cm⁻³ to 3×10¹⁸ cm⁻³. In the thus configured barrier layer 18, the p-AlGaAs layer 18b is depleted almost entirely in thermal equilibrium state.

On the surface of the i-AlGaAs layer 18c of the barrier layer 18, a gate electrode 20 is disposed. Although a T-shaped gate electrode 20 is used in this DCHFET 10, the gate electrode 20 must not necessarily be a T-shaped gate.

This gate electrode 20 is in Schottky contact with the i-AlGaAs layer 18c. The Schottky metal 20a of the gate electrode 20 is formed of tungsten silicide (WSi). An upper metal 20b on this Schottky metal 20a is formed of gold (Au) for wire bonding.

It is more effective for the p-AlGaAs layer 18b to have a thickness of 5 nm so that its depth from the bottom of the gate electrode 20 formed on the i-AlGaAs layer 18c falls within the range of 5 nm to 15 nm.

On the surface of the i-AlGaAs layer 18c of the barrier layer 18, a burying layer 22 is disposed so as to partly bury the sides of the foot of the T-shaped gate electrode 20. In this DCHFET 10 of the first embodiment, the burying layer 22 is composed of a 130 nm-thick i-GaAs layer.

On the surface of this burying layer 22, a source electrode 24 and a drain electrode 26 are disposed so as to face each other through the gate electrode 20.

Then, the following describes the operation of the DCHFET 10.

For example, the source electrode 24 is ground, a voltage of 12 V is applied to between the source electrode 24 and the drain electrode 26, and a bias of −0.2 V is applied to the gate electrode 20. Under this condition, a RF signal is input to between the source electrode 24 and the gate electrode 20. An output signal is output from the drain electrode 26.

Due to the p-AlGaAs layer 18b inserted in the barrier layer 18, the potential barrier in the barrier layer 18 is raised higher than the Schottky barrier-based potential barrier. Also in portions of the barrier layer 18 near the gate electrode 20 respectively between the gate electrode 20 and the source electrode 24 and between the gate electrode 20 and the drain electrode 26, the potential barrier is raised by the p-AlGaAs layer 18b in addition to the Schottky barrier-based potential barrier.

Since the potential barrier near the gate electrode 20 is made higher than the Schottky barrier-based potential barrier, the gate current to the gate electrode 20 when a forward bias is applied thereto is suppressed. It is therefore possible to raise the saturation output of the DCHFET 10.

Furthermore, since no highly doped n-type layer is included in the barrier layer 18, a longer depletion layer grows toward the drain electrode 26 when a reverse bias is applied to between the gate electrode 20 and the drain electrode 26. Therefore, since the intensification of electric field near the gate electrode 20 can be mitigated in the barrier layer 18, it is possible to raise the breakdown gate voltage.

Raising the breakdown gate voltage suppresses the gate leak current when the input signal is so raised as to saturate the output. Thus, since the input power is efficiently amplified, the DCHFET 10 is allowed to operate highly efficiently with high output.

For example, the DCFET 10 is actually used as a high power device with bias drain voltage Vd 12 V and bias gate voltage −0.4 V. If the RF input signal to the gate electrode 20 is so raised as to saturate the output, the input signal reaches to about 30 V at most. In this case, a reverse voltage of 30 V is applied to between the gate electrode 20 and the drain electrode 26.

In addition, since a longer depletion layer grows toward the drain electrode 26 when a reverse bias is applied to between the gate electrode 20 and the drain electrode 26, it is possible to reduce the gate to drain capacitance Cgd at RF operation and therefore improve the gain gm.

The barrier layer 18 has a three-layer structure composed of the i-AlGaAs layer 18a, p-AlGaAs layer 18b, and i-AlGaAs layer 18c. In the structure of the barrier layer 18, since the impurity concentration in the p-AlGaAs layer 18b, which is substantially fully depleted in thermal equilibrium state, can be raised, the height of the potential barrier to be raised by p-AlGaAs layer 18b can be increased.

Note that although the barrier layer 18 described above has a three-layer structure composed of the i-AlGaAs layer 18a, p-AlGaAs layer 18b, and i-AlGaAs layer 18c, the p-AlGaAs layer 18b lies between two i-AlGaAs layers. However, the p-AlGaAs layer 18b must not necessarily lies between two i-AlGaAs layers. For example, the barrier layer 18 may have a two-layer structure composed of a p-AlGaAs layer and an in-AlGaAs layer.

First Alternative

FIG. 2 is a cross-sectional view of an alternative heterojunction field effect transistor according to one embodiment of the present invention. Note that each reference numeral common to the drawings designates the elements identical or corresponding to each other.

In this DCHFET 30 shown in FIG. 2, the barrier layer 32 is composed of only a p-type semiconductor layer. The barrier layer 32 is a p-AlGaAs layer of, for example, 25 nm in thickness. However, the impurity concentration is 3×10¹⁷ cm⁻³, namely, somewhat lower than that in the barrier layer 18 of the DCHFET 10 in the first embodiment. This is because it is structurally difficult to deplete the barrier layer 32 in the DCHFET 30 at high temperature if the impurity concentration is so raised.

The other elements of the configuration are same as those in the DCHFET 10 of the first embodiment. This alternative provides substantially the same effect as the first embodiment whereas the configuration is simplified since the barrier layer 32 is composed of only a p-AlGaAs layer.

Second Alternative

FIG. 3 is a cross-sectional view of another alternative heterojunction field effect transistor according to one embodiment of the present invention.

In this DCHFET 35 shown in FIG. 3, n-type impurity-implanted regions 38 formed in ohmic regions respectively right below the source electrode 24 and the drain electrode 26.

The n-type impurity-implanted regions 38 are respectively right below the source electrode 24 and the drain electrode 26 and includes with the burying layer 22, the barrier layer 18, and the n-InGaAs layer 16 serving as a channel layer. The high density n-type impurity-implanted regions 38 are formed as follows. Anneal is performed after Si is selectively implanted in these regions, which are respectively right below the source electrode 24 and the drain electrode 26 and overlap with the burying layer 22, the barrier layer 18, and the n-InGaAs layer 16 serving as a channel layer. The impurity Si concentration in the n-type impurity-implanted regions 38 is about 3×10¹⁸ cm⁻³.

The other elements of the configuration are same as in the DCHFET 10. Note that although the present alternative is based on the DCHFET 10, forming the high density n-type impurity-implanted regions 38 in the DCHFET 30 provides substantially the same effect as well.

The high density n-type impurity-implanted regions 38 is formed to change the portions of the p-AlGaAs layer 18b respectively just below the source electrode 24 and the drain electrode 26 to heavily n-type regions. This reduces the DC[K1] resistances respectively between the n-InGaAs layer 16 serving as a channel layer and the source electrode 24 and between the n-InGaAs layer 16 serving as a channel layer and the drain electrode 26. Therefore, the DCHFET 30 can realize a higher gain in addition to the effect described with the DCHFET 10.

As mentioned above, in the heterojunction field effect transistor according to the first embodiment, the barrier layer is disposed on the channel layer and is composed of only either a substantially fully depleted p-type semiconductor layer or a substantially fully depleted p-type semiconductor layer and non-doped semiconductor layers. Therefore, the p-type semiconductor layer makes the potential barrier in the barrier layer being higher than the Schottky barrier-based potential barrier. In addition, since the potential barrier near the gate electrode is further raised than the Schottky barrier-based potential barrier, the forward gate current can be suppressed. Consequently, it is possible to raise the saturation output.

In addition, since a longer depletion layer grows toward the drain side when a reverse bias is applied to between the gate and the drain, the intensification of electric field near the gate electrode can be mitigated to raise the breakdown gate voltage. Thus, since the input power is efficiently amplified, it is possible to operate highly efficiently with high output.

Furthermore, due to the longer depletion layer growing toward the drain side when a reverse bias is applied to between the gate and the drain, it is possible to reduce the gate to drain capacitance Cgd at RF operation and therefore improve the gain gm.

Consequently, it is possible to provide a simply configured high output, high efficiency, and high gain heterojunction field effect transistor at low cost.

### Second Embodiment

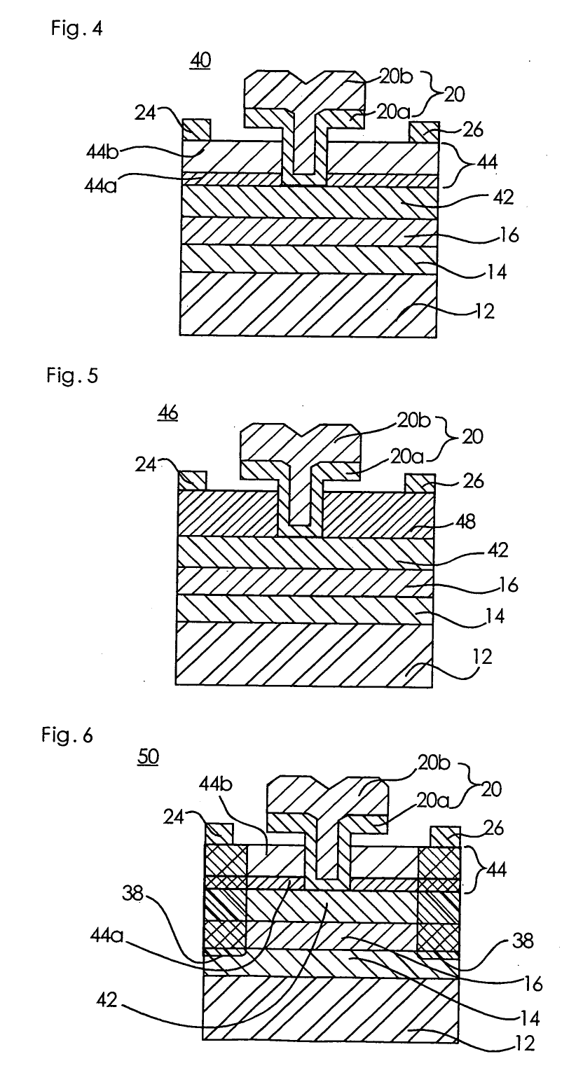

FIG. 4 is a cross-sectional view of another heterojunction field effect transistor according to another embodiment of the present invention.

FIG. 4 shows a DCHFET 40 of the heterojunction field effect transistor of the second embodiment. The CHFET 40 is similar to the DCHFET 10 of the first embodiment, but the CHFET 40 is different from the DCHFET 10 in the following two points. First, the barrier layer 42 is composed of a 25 nm-thick i-AlGaAs layer. Second, the 130 nm-thick burying layer 44 disposed on the barrier layer 42 is composed of two layers. The burying layer 44 is composed of a lower burying layer 44a and an upper burying layer 44b. The lower burying layer is in contact with the barrier layer 42 and is composed of a p-GaAs layer, which is substantially fully depleted in thermal equilibrium state. The upper burying layer 44b is composed of an i-GaAs layer. The other elements of the configuration are same as the DCHFET 10 of the first embodiment.

The lower burying layer 44a is 5 nm to 20 nm thick and has an impurity concentration of 1×10¹⁸ cm⁻³ to 3×10¹⁸ cm⁻³.

This double-layered burying layer 44 makes it possible to raise the impurity concentration in the lower burying layer 44a, which is substantially fully depleted in thermal equilibrium state. Therefore, the height of the potential barrier to be raised by the p-GaAs layer of the lower burying layer 44a is increased.

In the DCHFET 40 of the second embodiment, the burying layer 44 is disposed so as to partly bury the sides of the foot of the T-shaped gate electrode 20. The lower burying layer 44a of the burying layer 44 is composed of a p-GaAs layer, which is substantially fully depleted in thermal equilibrium state. Accordingly, the potential barrier near the gate electrode 20 either between the gate electrode 20 and the source electrode 24 or between the gate electrode 20 and the drain electrode 26 is raised by the lower burying layer 44a in addition to the Schottky barrier-based potential barrier.

Thus, the potential barrier near the gate electrode 20 either between the gate electrode 20 and the source electrode 24 or between the gate electrode 20 and the drain electrode 26 is higher than the Schottky barrier-based potential barrier. When a forward bias is applied to the gate electrode 20, the gate current is suppressed. It is therefore possible to raise the saturation output of the DCHFET 40.

In addition, similar to the first embodiment, since the barrier layer 18 is composed of a non-doped layer, a longer depletion layer grows toward the drain electrode 26 when a reverse bias is applied to between the gate electrode 20 and the drain electrode 26. Therefore, since the intensification of electric field near the gate electrode 20 can be mitigated, it is possible to raise the breakdown gate voltage.

Raising the breakdown gate voltage suppresses the gate leak current when the input signal is so raised as to saturate the output. Since the input power is efficiently amplified, the DCHFET 40 is allowed to operate highly efficiently with high output.

Furthermore, due to the longer depletion layer growing toward the drain electrode 26 when a reverse bias is applied to between the gate electrode 20 and the drain electrode 26, it is possible to reduce the gate to drain capacitance Cgd at RF operation and therefore improve the gain gm.

In the second embodiment described, the upper burying layer 44b of i-GaAs layer is disposed on the lower burying layer 44a of p-GaAs layer. However, the burying layer must not necessarily be configured in this manner. The burying layer may be composed of a p-GaAs layer lying between two i-GaAs layers.

Third Alternative

FIG. 5 is a cross-sectional view of an alternative heterojunction field effect transistor according to one embodiment of the present invention.

The DCHFET 46 of the third alternative shown in FIG. 5 is same as the DCHFET 40 except that the burying layer 48 is composed of only a 130 nm-thick p-GaAs layer, which is substantially fully depleted in thermal equilibrium state. The other elements of the configuration are same as the DCHFET 40. Accordingly, the DCHFET 46 provides substantially the same effect as the DCHFET 40.

However, the burying layer 48 is thicker than the lower burying layer 44a in the DCHFET 40, the burying layer hard to be fully depleted at high temperature unless the impurity concentration is lower than in the lower burying layer 44a.

Although the potential barrier raised by the burying layer 48 is therefore lower than the potential barrier raised by the lower burying layer 44a of p-GaAs layer, the DCHFET 46 can be configured simply since the burying layer 48 is composed of only a p-GaAs layer.

Fourth Alternative

FIG. 6 is a cross-sectional view of another alternative heterojunction field effect transistor according to one embodiment of the present invention.

In the DCHFET 50 shown in FIG. 6, n-type impurity-implanted regions 38 are formed in ohmic regions respectively right below the source electrode 24 and the drain electrode 26.

The n-type impurity-implanted regions 38 are respectively right below the source electrode 24 and the drain electrode 26 and includes the burying layer 44, the barrier layer 42, and the n-InGaAs layer 16 serving as a channel layer. The high density n-type impurity-implanted regions 38 are formed as follows. Anneal is performed after Si is selectively implanted in these regions, which are respectively right below the source electrode 24 and the drain electrode 26 and overlap with the burying layer 44, the barrier layer 42, and the n-InGaAs layer 16 serving as a channel layer. The impurity Si concentration in the n-type impurity-implanted regions 38 is about 3×10¹⁸ cm⁻³.

The other elements of the configuration are same as in the DCHFET 40. Note that although the present alternative is based on the DCHFET 40, forming the high density n-type impurity-implanted regions 38 in the DCHFET 46 provides substantially the same effect as well.

The high density n-type impurity-implanted regions 38 is formed to change portions of the p-GaAs layer of the lower burying layer 44a respectively just below the source electrode 24 and the drain electrode 26 to heavily n-type regions. This reduces the DC[K2] resistances respectively between the n-InGaAs layer 16 serving as a channel layer and the source electrode 24 and between the n-InGaAs layer 16 serving as a channel layer and the drain electrode 26. Therefore, the DCHFET 50 can realize a higher gain in addition to the effect described with the DCHFET 40.

As mentioned above, the heterojunction field effect transistor according to the second embodiment has: a non-doped barrier layer disposed on the channel layer; and a substantially fully depleted p-type semiconductor layer disposed on the barrier layer so as to partly bury the sides of the foot of the gate electrode, which is formed on the barrier layer and is in Schottky contact with the barrier layer. Therefore, the potential barrier near the gate electrode is made higher than the Schottky barrier-based potential barrier. This makes it possible to suppress the forward gate current and therefore raise the saturation output.

In addition, since a longer depletion layer grows toward the drain side when a reverse bias is applied to between the gate and the drain, the intensification of electric field near the gate electrode can be mitigated to raise the breakdown gate voltage. Thus, since the input power is efficiently amplified, it is possible to operate highly efficiently with high output.

Furthermore, due to the longer depletion layer growing toward the drain side when a reverse bias is applied to between the gate and the drain, it is possible to reduce the gate to drain capacitance Cgd at RF operation and therefore improve the gain gm.

Consequently, it is possible to provide a simply configured high output, high efficiency, and high gain heterojunction field effect transistor at low cost.

### Third Embodiment

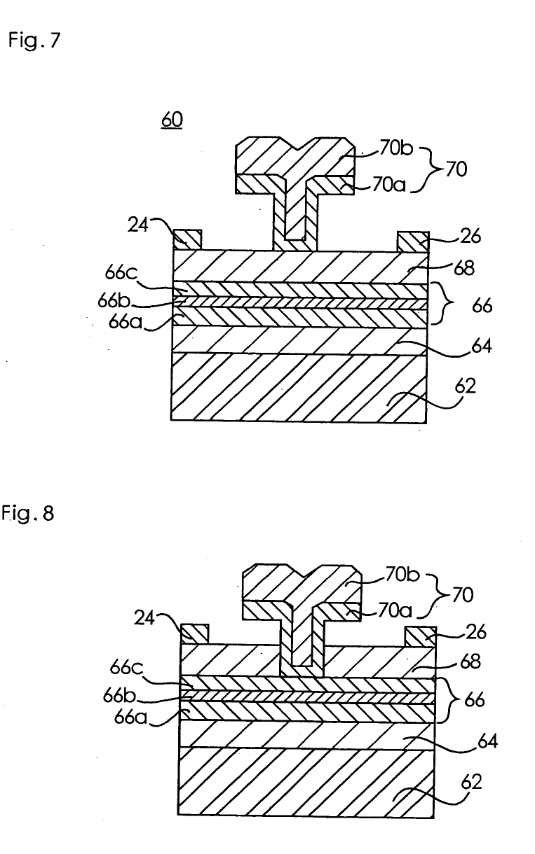

FIG. 7 is a cross-sectional view of another heterojunction field effect transistor according to another embodiment of the present invention.

FIG. 7 shows a HEMT 60 of the heterojunction field effect transistor of the third embodiment.

The HEMT 60 uses a SiC substrate 62 as an insulating substrate. This SiC substrate 62 may be replaced by a sapphire substrate. It is also possible to use a semi-insulating semiconductor substrate. On the SiC substrate 62, an i-GaN layer 64 having a thickness of, for example, 30 nm is disposed as a channel layer. On this i-GaN layer 64, a barrier layer 66 is disposed. In this example of the third embodiment, the barrier layer 66 has a thickness of 30 nm and is composed of an i-Al_{0.25}GaN layer 66a in contact with the i-GaN layer 64, a p-Al_{0.25}GaN layer 66b disposed on the i-Al_{0.25}GaN layer 66a, and an i-Al_{0.25}GaN layer 66c disposed on the p-Al_{0.25}GaN layer 66b. In the thus configured barrier layer 66, the p-Al_{0.25}GaN layer 66b is depleted almost entirely in thermal equilibrium state.

The p-Al_{0.25}GaN layer 66b has a thickness of 5 nm to 20 nm and an impurity concentration of 1×10¹⁸ cm⁻³ to 2×10¹⁹ cm⁻³. Compared with a GaAs-based p-type layer, this p-Al_{0.25}GaN layer 66b must have a somewhat higher impurity concentration with the same thickness. This is because a higher impurity concentration is needed to compensate for a higher electron carrier concentration in GaN-based material.

In the interface between the i-GaN layer 64 and the i-Al_{0.25}GaN layer 66a, a two-dimensional electron gas layer is formed on the i-GaN layer 64 side due to the respective crystal periods. Therefore, it is not necessary that a layer on the i-GaN layer 64 serving as a channel layer, which is the i-Al_{0.25}GaN layer 66a in the present embodiment, is formed as an n-type layer. This i-Al_{0.25}GaN layer 66a sufficiently serves as an electron supplier layer.

On the barrier layer 66, a contact layer 68 composed of an n-Al_{0.25}GaN layer having a thickness of, for example, 3 nm is disposed. On the surface of the contact layer 68, a gate electrode 70 is disposed. Although the HEMT 60 uses a T-shaped gate electrode, the gate electrode must not necessarily be of this type.

The gate electrode 70 is in Schottky contact with the n-Al_{0.25}GaN contact layer 68. This gate electrode 70 is composed of a Schottky metal 70a and an upper metal 70b, which is formed on the Schottky metal 70a. The Schottky metal 70a is made of nickel (Ni). The upper metal 70b made of gold (Au) is formed for wire bonding.

On the surface of the contact layer 68, a source electrode 24 and a drain electrode 26 are formed so as to face each other through the gate electrode 70.

FIG. 8 is a cross-sectional view of an alternative heterojunction field effect transistor according to one embodiment of the present invention.

Although the gate electrode 70 in FIG. 7 is in Schottky contact with the n-Al_{0.25}GaN contact layer 68, the gate electrode 70 may also be disposed on the i-Al_{0.25}GaN contact layer 66c of the barrier layer 66 so as to have Schottky contact with the i-Al_{0.25}GaN contact layer 66c as shown in FIG. 8.

In the HEMT 60, due to the p-Al_{0.25}GaN layer 66b inserted in the barrier layer 66, the potential barrier in the barrier layer 66 is raised higher than the Schottky barrier-based potential barrier. Also the potential barrier near the gate electrode 70 either between the gate electrode 70 and the source electrode 24 or between the gate electrode 70 and the drain electrode 26 is raised by the p-Al_{0.25}GaN layer 66b in addition to the Schottky barrier-based potential barrier.

The potential barrier near the gate electrode 70 is made higher than the Schottky barrier-based potential barrier. When a forward bias is applied to the gate electrode 70, the gate current is suppressed. It is therefore possible to raise the saturation output of the HEMT 60.

Furthermore, since no highly doped n-type layer is included in the barrier layer 66, a longer depletion layer grows toward the drain electrode 26 when a reverse bias is applied to between the gate electrode 70 and the drain electrode 26. Therefore, since the intensification of electric field near the gate electrode 70 can be mitigated in the barrier layer 66, it is possible to raise the breakdown gate voltage.

Raising the breakdown gate voltage suppresses the gate leak current when the input signal is so raised as to saturate the output. Thus, since the input power is efficiently amplified, the HEMT 60 is allowed to operate highly efficiently with high output.

In addition, since a longer depletion layer grows toward the drain electrode 26 when a reverse bias is applied to between the gate electrode 70 and the drain electrode 26, it is possible to reduce the gate to drain capacitance Cgd at RF operation and therefore improve the gain gm.

The barrier layer 66 has a three-layer structure composed of the i-Al_{0.25}GaN layer 66a, p-Al_{0.25}GaN layer 66b, and i-Al_{0.25}GaN layer 66c. Since the impurity concentration in the p-Al_{0.25}GaN layer 66b, which is substantially fully depleted in thermal equilibrium state, can be raised, the height of the potential barrier to be raised by the p-Al_{0.25}GaN layer 66b can be increased.

As described above, the HEMT 60 has a three-layer structure such that the barrier layer 66 has the p-Al_{0.25}GaN layer 66b between the i-Al_{0.25}GaN layer 66a and i-Al_{0.25}GaN layer 66c. However, the barrier layer 66 must not necessarily have this configuration. For example, the barrier layer 66 may have a two-layer structure composed of a p-Al_{0.25}GaN layer and an i-Al_{0.25}GaN layer.

It is also possible to form the barrier layer 66 only by a p-Al_{0.25}GaN layer. In this case, it is possible to provide almost the same effect as the HEMT 60 while the configuration is simplified.

As mentioned above, the heterojunction field effect transistor according to the third embodiment comprises, a channel layer of non-doped semiconductor, a barrier layer disposed on the channel layer and composed of only either a substantially fully depleted p-type semiconductor layer or a substantially fully depleted p-type semiconductor layer and non-doped semiconductor layers. Therefore, the p-type semiconductor layer makes the potential barrier in the barrier layer higher than the Schottky barrier-based potential barrier. In addition, since the potential barrier near the gate electrode is further raised than the Schottky barrier-based potential barrier, the forward gate current can be suppressed. It is therefore possible to raise the saturation output.

In addition, since a longer depletion layer grows toward the drain side when a reverse bias is applied to between the gate and the drain, the intensification of electric field near the gate electrode can be mitigated to raise the breakdown gate voltage. Thus, since the input power is efficiently amplified, it is possible to operate highly efficiently with high output.

Furthermore, due to the longer depletion layer growing toward the drain side when a reverse bias is applied to between the gate and the drain, it is possible to reduce the gate to drain capacitance Cgd at RF operation and therefore improve the gain gm.

Consequently, it is possible to provide a simply configured high output, high efficiency, and high gain heterojunction field effect transistor at low cost.

As mentioned above, the heterojunction field effect semiconductor device of the present invention is suitable to high power amplifiers and the like used in the micro wave to millimeter wave bands.

While the presently preferred embodiments of the present invention have been shown and described. It is to be understood these disclosures are for the purpose of illustration and that various changes and modifications may be made without departing from the scope of the invention as set forth in the appended claims.

1. A heterojunction field effect semiconductor device comprising:
a semi-insulating semiconductor substrate;
a n-type semiconductor channel layer disposed on the substrate;
a barrier layer disposed on the channel layer and composed of only either (i) a substantially fully depleted p-type semiconductor layer or (ii) a substantially fully depleted p-type semiconductor layer and non-doped semiconductor layers;
a gate electrode disposed on the barrier layer and in Schottky contact with the barrier layer; and
a source electrode and a drain electrode disposed on the barrier layer, facing each other, on opposite sides of the gate electrode.

2. The heterojunction field effect semiconductor device according to claim 1, wherein the barrier layer is composed of only the p-type semiconductor layer and the non-doped semiconductor layers and comprises a p-type semiconductor layer disposed between two non-doped semiconductor layers.

3. A heterojunction field effect semiconductor device comprising:
a semi-insulating semiconductor substrate;
a n-type semiconductor channel layer disposed on the substrate;
a non-doped barrier layer disposed on the channel layer;
a gate electrode disposed on the barrier layer and in Schottky contact with the barrier layer;
a p-type semiconductor layer which is substantially fully depleted, disposed on the barrier layer, partly burying sides of the gate electrode; and
a source electrode and a drain electrode that are disposed on the p-type semiconductor layer, facing each other, on opposite sides of the gate electrode.

4. The heterojunction field effect semiconductor device according to claim 3, further comprising a non-doped semiconductor layer on the p-type semiconductor layer.

5. The heterojunction field effect semiconductor device according to claim 1, further comprising n-type impurity regions, respectively located just below the source electrode and the drain electrode, extending from the channel layer to the bottom of the source electrode and of the drain electrodes, including the channel layer.

6. The heterojunction field effect semiconductor device according to claim 3, further comprising n-type impurity regions, respectively located just below the source electrode and the drain electrodes, extending from the channel layer to the bottom of the source electrode and of the drain electrode, including the channel layer.

7. A heterojunction field effect semiconductor device comprising:
a semi-insulating semiconductor substrate;
a channel layer of a non-doped semiconductor disposed on the substrate;
a barrier layer disposed on the channel layer, and composed of only either (i) a substantially fully depleted p-type semiconductor layer or (ii) a substantially fully depleted p-type semiconductor layer and non-doped semiconductor layers;
a gate electrode disposed on the barrier layer; and
a source electrode and a drain electrode disposed on the barrier facing each other, opposite sides of the gate electrode.

8. The heterojunction field effect semiconductor device according to claim 7, wherein the barrier layer is composed of only the p-type semiconductor layer and the non-doped semiconductor layers and comprises a p-type semiconductor layer disposed between two non-doped semiconductor layers.
